(19) United States
(12) Patent Application Publication
(10) Pub. No.: US 2006/0289291 A1
(43) Pub. Date: Dec. 28, 2006

(54) Method for adjusting electromagnetic field across a front side of a sputtering target disposed inside a chamber

(75) Inventors: Hienminh H. Le, San Jose, CA (US); Akihiro Hosokawa, Cupertino, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/167,520

(22) Filed: Jun. 27, 2005

(51) Int. Cl. C23C 14/32; C23C 14/00

(52) U.S. Cl. 204/192.1; 204/298.16

(57) ABSTRACT

A physical vapor deposition chamber, which includes a sputtering target, a magnetron disposed on a back side of the sputtering target, a metal sheet disposed between at least a portion of the magnetron and the sputtering target to reduce the effect of the magnetic strength of the portion of the magnetron on the sputtering target and a substrate support for holding a substrate.

### BACKGROUND OF THE INVENTION

1. Field of the Invention

Embodiments of the present invention generally relate to substrate processing systems, such as physical vapor deposition systems.

2. Description of the Related Art

Physical vapor deposition (PVD) is one of the most commonly used processes in fabrication of electronic devices, such as flat panel displays. PVD is a plasma process performed in a vacuum chamber where a negatively biased target is exposed to a plasma of an inert gas having relatively heavy atoms (e.g., argon) or a gas mixture comprising such inert gas. Bombardment of the target by ions of the inert gas results in ejection of atoms of the target material. The ejected atoms accumulate as a deposited film on a substrate placed on a substrate pedestal disposed underneath the target within the chamber. Flat panel sputtering is principally distinguished from the long developed technology of wafer sputtering by the large size of the substrates and their rectangular shape.

Films deposited using current PVD chambers, however, often lack uniform thickness. This phenomenon may be caused by uneven plasma distribution across the target. For example, the plasma density at the edge of the target may be high, while the plasma density at the center of the target may be low, which leads to a deposition of film having uneven thickness.

Therefore, a need exists in the art for a method for adjusting electromagnetic field across a front side of a sputtering target.

### SUMMARY OF THE INVENTION

Embodiments of the invention are directed to a method for adjusting an electromagnetic field across a front side of a sputtering target disposed inside a chamber. The method includes depositing a layer of film on a substrate disposed facing the front side of the sputtering target. The layer of film comprises material from the target. The method further includes identifying one or more areas on the layer of film having an undesired thickness and adjusting one or more magnet pieces that correspond with the areas on the layer of film having the undesired thickness. The magnet pieces are disposed on a back side of the sputtering target and the back side is opposite of the front side.

Embodiments of the invention are also directed to a physical vapor deposition chamber, which includes a sputtering target, a magnetron disposed on a back side of the sputtering target, a metal sheet disposed between at least a portion of the magnetron and the sputtering target to reduce the effect of the magnetic strength of the portion of the magnetron on the sputtering target and a substrate support for holding a substrate.

Embodiments of the invention are also directed to a method for processing a substrate in a physical vapor deposition chamber. The method includes providing a sputtering target, providing a magnetron on a back side of the sputtering target and changing the configuration of the magnetron to increase uniformity of deposition on the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process chamber that may be used in connection with one or more embodiments of the invention.

FIG. 2 illustrates a linear magnetron that may be used in connection with one or more embodiments of the invention.

FIG. 3 illustrates a schematic view of a serpentine magnetron that may be used in connection with one or more embodiments of the invention.

FIG. 4 illustrates a schematic view of a spiral magnetron that may be used in connection with one or more embodiments of the invention.

FIG. 5 illustrates a serpentine magnetron that may be used in connection with one or more embodiments of the invention.

FIG. 6 illustrates a double-digitated magnetron that may be used in connection with one or more embodiments of the invention.

FIG. 7 illustrates a rectangularized spiral magnetron that may be used in connection with one or more embodiments of the invention.

FIG. 8 illustrates a flow diagram of a method for adjusting the electromagnetic field across the front side of the sputtering target in accordance with one or more embodiments of the invention.

FIG. 9A illustrates a schematic diagram of a metal sheet being disposed between a sputtering target and a magnetron in accordance with one or more embodiments of the invention.

FIG. 9B illustrates a schematic diagram of replacing magnet pieces with weaker magnet pieces to reduce the electromagnetic field in accordance with one or more embodiments of the invention.

FIG. 9C illustrates a schematic diagram of removing magnet pieces to reduce the electromagnetic field in accordance with one or more embodiments of the invention.

FIG. 9D illustrates a schematic diagram of replacing magnet pieces with stronger magnet pieces to increase the electromagnetic field in accordance with one or more embodiments of the invention.

### DETAILED DESCRIPTION

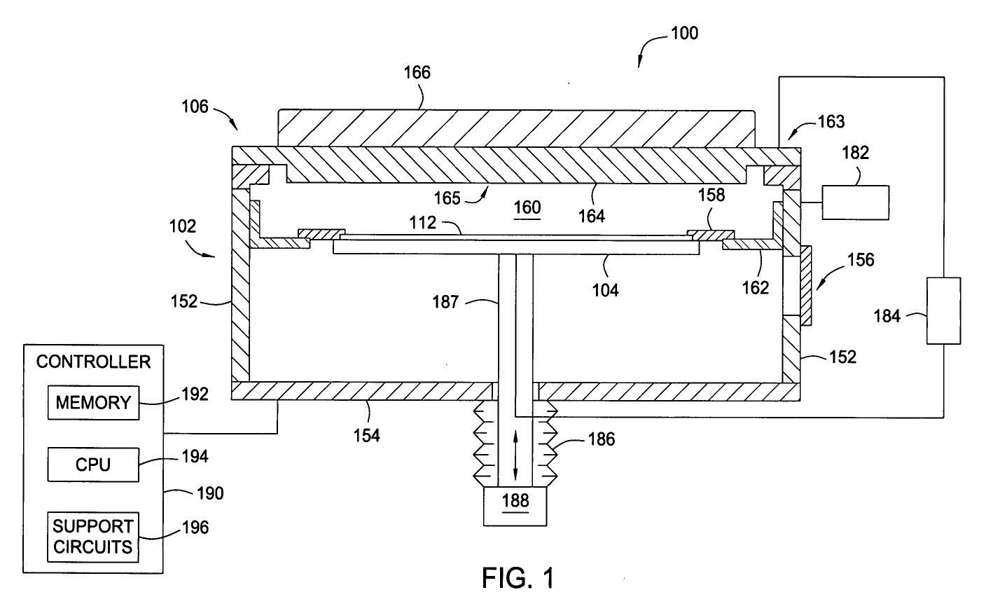

FIG. 1 illustrates a process chamber 100 that may be used in connection with one or more embodiments of the invention. One example of a process chamber 100 that may be adapted to benefit from the embodiments of the invention is a PVD process chamber, available from AKT, Inc., located in Santa Clara, Calif.

The process chamber 100 includes a chamber body 102 and a lid assembly 106 that define an evacuable process volume 160. The chamber body 102 is typically fabricated from welded stainless steel plates or a unitary block of aluminum. The chamber body 102 generally includes sidewalls 152 and a bottom 154. The sidewalls 152 and/or bottom 154 may include a plurality of apertures, such as an access port 156, a shutter disk port (not shown) and a pumping port (not shown). The access port 156 provides for entrance and egress of a substrate 112 to and from the process chamber 100. The pumping port is typically coupled to a pumping system that evacuates and controls the pressure within the process volume 160.

A substrate support 104 is disposed inside the chamber body 102 and is configured to support the substrate 112 thereupon during processing. The substrate support 104 may be fabricated from aluminum, stainless steel, ceramic or combinations thereof. A shaft 187 extends through the bottom 154 of the chamber body 102 and couples the substrate support 104 to a lift mechanism 188. The lift mechanism 188 is configured to move the substrate support 104 between a lower position and an upper position. A bellows 186 is typically disposed between the lift mechanism 188 and the chamber bottom 154 and provides a flexible seal therebetween, thereby maintaining vacuum integrity of the process volume 160.

Optionally, a bracket 162 and a shadow frame 158 may be disposed within the chamber body 102. The bracket 162 may be coupled to the sidewall 152 of the chamber body 102. The shadow frame 158 is generally configured to confine deposition to a portion of the substrate 112 exposed through the center of the shadow frame 158. When the substrate support 104 is moved to the upper position for processing, an outer edge of the substrate 112 disposed on the substrate support 104 engages the shadow frame 158 and lifts the shadow frame 158 from the bracket 162. Alternatively, shadow frames having other configurations may optionally be utilized as well.

The substrate support 104 may be moved into a lower position for loading and unloading the substrate 112 from the substrate support 104. In the lower position, the substrate support 104 is positioned below the bracket 162 and the access port 156. The substrate 112 may then be removed from or placed into the chamber 100 through the access port 156. Lift pins (not shown) may be selectively moved through the substrate support 104 to space the substrate 112 away from the substrate support 104 to facilitate the placement or removal of the substrate 112 by a wafer transfer mechanism disposed exterior to the process chamber 100.

The lid assembly 106 generally includes a target 164, which is configured to provide material that is deposited on the substrate 112 during the PVD process. The target 164 may include a peripheral portion 163 and a central portion 165. The peripheral portion 163 is typically disposed over the sidewalls 152. The central portion 165 of the target 164 may protrude, or extend in a direction, towards the substrate support 104. It is contemplated that other target configurations may be utilized as well. For example, the target 164 may include a backing plate having a central portion of a desired material bonded or attached thereto. The target material may also include adjacent tiles or segments of material that together form the target 164.

The target 164 and substrate support 104 may be biased relative to each other by a power source 184. A gas, such as argon, may be supplied to the process volume 160 from a gas source 182 through one or more apertures (not shown), which may be formed in the sidewalls 152 of the process chamber 100. The biasing of the target 164 and the substrate support 104 generate an electromagnetic field such that a plasma may be formed between the substrate 112 and the target 164. Ions within the plasma are accelerated toward the target 164 and cause material to become dislodged from the target 164. The dislodged material is attracted towards the substrate 112 and deposits a film of material thereon.

The process chamber 100 may be in communication with a controller 190, which typically includes a central processing unit (CPU) 194, support circuits 196 and memory 192. The CPU 194 may be one of any form of computer processor that can be used in an industrial setting for controlling various chambers and sub-processors. The memory 192 is coupled to the CPU 194. The memory 192 may be a computer-readable medium or one or more of readily available memory, such as random access memory (RAM), read only memory (ROM), floppy disk, hard disk, or any other form of digital storage, local or remote. The support circuits 196 are coupled to the CPU 194 for supporting the CPU 194 in a conventional manner. These circuits 196 may include cache, power supplies, clock circuits, input/output circuitry, subsystems, and the like. The controller 190 may be used to control operation of the process chamber 100, including any deposition processes performed therein.

The lid assembly 106 may further include a magnetron 166, which enhances consumption of the target material during processing. The following paragraphs describe various types of magnetrons that may be used in connection with one or more embodiments of the invention.

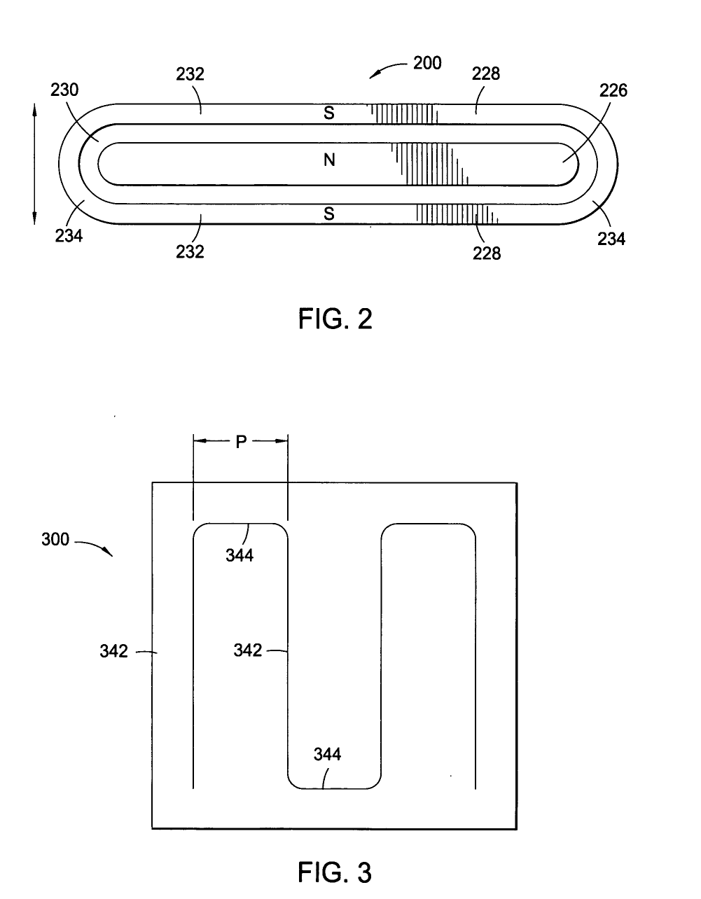

FIG. 2 illustrates a linear magnetron 200 that may be used in connection with one or more embodiments of the invention. The linear magnetron 200 includes a central pole 226 of one vertical magnetic polarity surrounded by an outer pole 228 of the opposite polarity to project a magnetic field within the chamber 100 and parallel to the front side of the target 164. The two poles 226, 228 are separated by a substantially constant gap 230 over which a high-density plasma is formed under the correct chamber conditions and flows in a close loop or track. The outer pole 228 includes two straight portions 232 connected by two semi-circular arc portions 234. The magnetic field traps electrons and thereby increases the density of the plasma, which in turn increases the sputtering rate. The relatively small widths of the linear magnetron 200 and of the gap 230 produce a higher magnetic flux density. The closed shape of the magnetic field distribution along a single closed track forms a plasma loop generally following the gap 230 and prevents the plasma from leaking out the ends. Although horseshoe magnets may be used, the preferred structure includes a large number of strong cylindrical magnet pieces that may be made from materials, such as, NdBFe arranged in the indicated pole shapes with their orientations inverted between the two indicated polarities.

FIG. 3 illustrates a schematic view of a serpentine magnetron 300 that may be used in connection with one or more embodiments of the invention. The serpentine magnetron 300 may include multiple long parallel straight portions 342 arranged on a pitch P smoothly joined by end portions 344, which may be arc shaped or alternatively short straight portions with curved corners connecting to the straight portions 342.

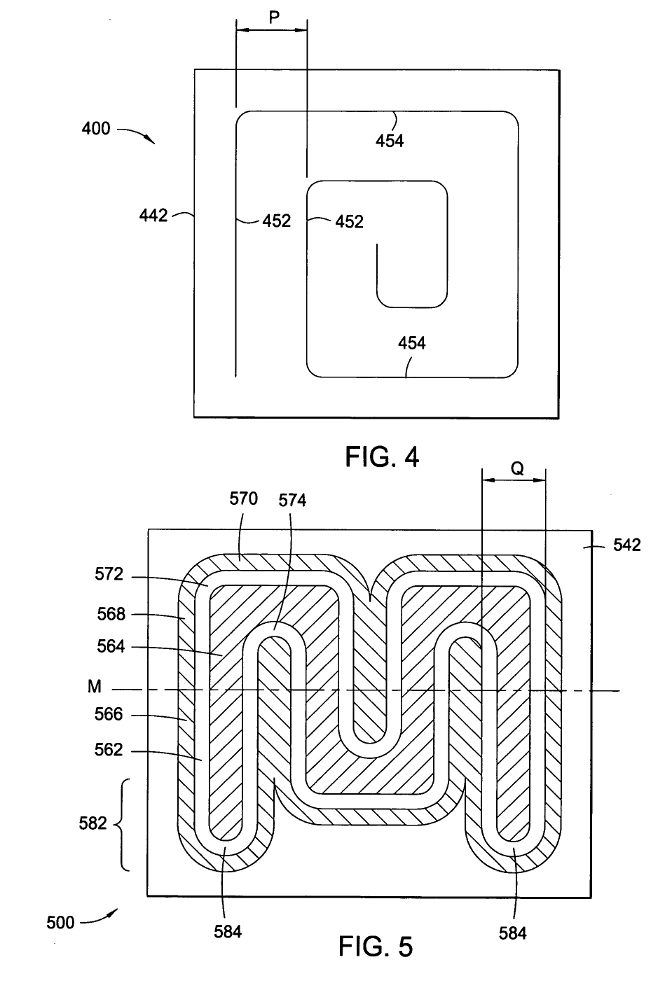

FIG. 4 illustrates a schematic view of a spiral magnetron 400 that may be used in connection with one or more embodiments of the invention. The spiral magnetron 400 may include a continuous series of straight portions 452 and 454 extending along perpendicular axes and smoothly joined together in a rectangular spiral. Neighboring parallel straight portions 452 or 454 are separated by a track pitch P. The number of folds in either magnetron 300 or magnetron 400 may be significantly increased. Although it is not necessary, each of the magnetrons may be considered a folded or twisted version of an extended racetrack magnetron of FIG. 2 with a plasma loop formed between the inner pole and the surrounding outer pole. When the linear magnetron 200 of FIG. 2 is folded, the poles of neighboring folds may merge.

FIG. 5 illustrates a serpentine magnetron 500 that may be used in connection with one or more embodiments of the invention. The serpentine magnetron 500 may be formed of a closed serpentine gap 562 between an inner pole 564 and an outer pole 566 completely surrounding the inner pole 564. The plasma loop includes two closely spaced anti-parallel propagating plasma tracks separated by a track pitch Q and folded to form a structure that is generally periodic in the illustrated x-direction with a period of the track pitch Q. The single folded track and hence the magnetron have a shape generally following long straight portions 568 extending symmetrically in one direction about a medial line M and shorter straight portions 570 extending in the other directions. Curved portions 572, 574, connect the straight portions 568, 570. The inner curved portion 574 curves sharply around 180°. It is understood that the serpentine magnetron 500 may include additional folds of the plasma loop, particularly for larger target sizes. The serpentine magnetron 500 may also include tail portions 582 in which both the inner and outer poles 564, 566 have been extended in the region surrounding end curved portions 584 of the gap 572 so that the end curved portions 584 are outside of a rectangular outline of the useful area of the magnetron 500. It is understood that if the plasma loop has an odd number of folds, the two tail portions 582 occur on opposed lateral sides of the magnetron plate 542.

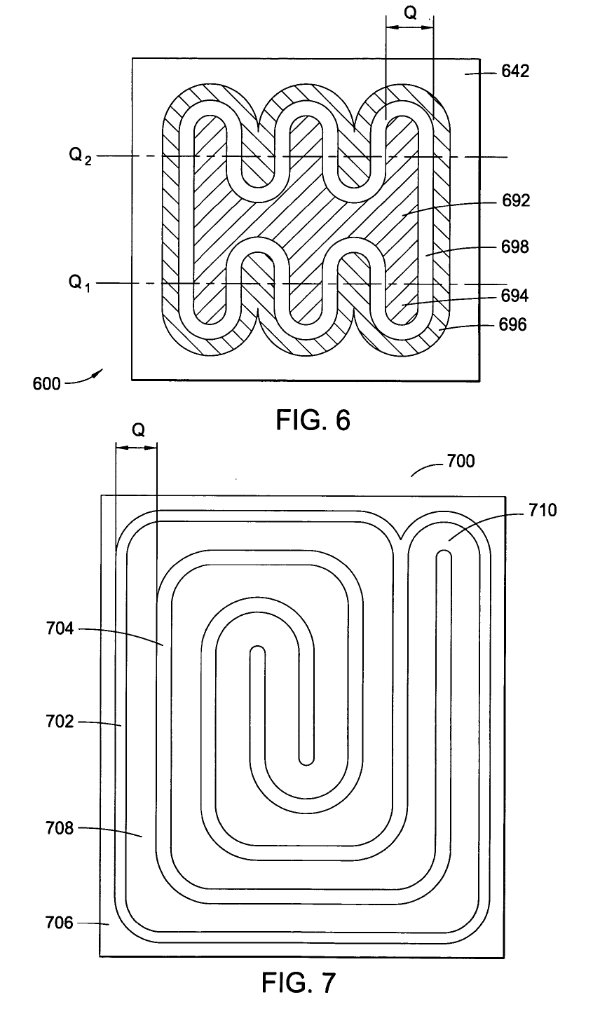

FIG. 6 illustrates a double-digitated magnetron 600 that may be used in connection with one or more embodiments of the invention. The double-digitated magnetron 600 includes an inner pole 692 formed of two opposed rows of generally straight teeth portions 694 and a surrounding outer pole 696 separated from the inner pole 692 by a closed gap 698. The straight portions of the gap 698 are arranged about two general symmetry lines Q₁ and Q₂. The serpentine magnetron 500 and double-digitated magnetron 600, although visually different, are topologically similar and provide similar magnetic field distributions. Both advantageously have straight portions constituting at least 50% and preferably more than 75% of the total track length. The digitated magnetron 600 is, however, distinguished from the serpentine magnetron 500 and the rectangularized spiral (or helical) magnetron 700 (to be described later) by its inner pole 692 having a complex shape with many projections and not describable in terms of a single path. In contrast, the inner pole of the serpentine and helical magnetrons has a nearly constant width that follows a single convolute or folded path extending from one end to the other. Expressed differently, the inner pole of serpentine and helical magnetrons has only two ends defining ends of the closed plasma loop, while the inner pole of the digitated magnetron has three or more ends with many equivalent ends to the plasma loop.

FIG. 7 illustrates a rectangularized spiral magnetron 700 that may be used in connection with one or more embodiments of the invention. The rectangularized spiral magnetron 700 includes continuous grooves 702, 704 formed in a magnetron plate 706. Unillustrated cylindrical magnets of opposed polarities respectively fill the two grooves 702, 704. The groove 702 completely surrounds the groove 704. The two grooves 702, 704 are arranged on a track pitch Q and are separated from each other by a mesa 708 of substantially constant width. In the context of the previous descriptions, the mesa 708 represents the gap between the opposed poles. The one groove 702 represents the outer pole. The other groove 704 represents the inner pole which is surrounded by the outer pole. Similarly to the racetrack magnetron, whether twisted or not, one magnetic pole represented by the groove 704 is completely surrounded by the other magnetic pole represented by the groove 702, thereby intensifying the magnetic field and forming one or more plasma loops to prevent end loss. The width of the outermost portions of the groove 702 is only slightly more than half the widths of the inner portions of that groove 702 and of all the portions of the other groove 704 since the outermost portions accommodate only a single row of magnets while the other groove portions accommodate two rows in staggered arrangements. The grooves 702, 704 of the magnetron 700 may be modified to include a tail portion around a 180° curved end 710 of the mesa 708, similar to the tail portions 582 of FIG. 5. A single magnetic yoke plate may cover the back of the magnetron plate 706 to magnetically couple all the magnets. Various magnetrons described herein may be further described in more detail in commonly assigned U.S. patent application Ser. No. 10/863,152, filed Jun. 7, 2004 and entitled Two Dimensional Magnetron Scanning for Flat Panel Sputtering, which is incorporated herein by reference.

Other convolute shapes for the magnetron may be used in connection with one or more embodiments of the invention. For example, serpentine and spiral magnetrons can be combined in different ways. A spiral magnetron may be joined to a serpentine magnetron, both being formed with a single plasma loop. Two spiral magnetrons may be joined together, for example, with opposite twists. Two spiral magnetrons may bracket a serpentine magnetron.

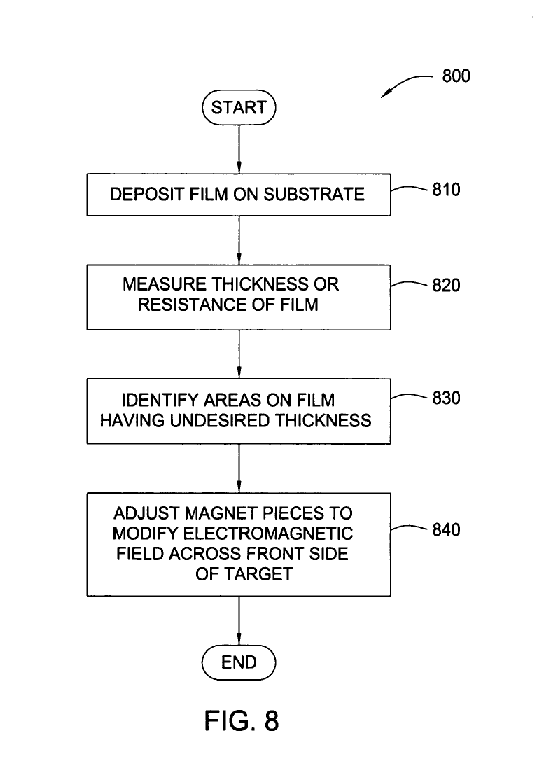

FIG. 8 illustrates a flow diagram of a method 800 for adjusting the electromagnetic field across the front side of the sputtering target 164 in accordance with one or more embodiments of the invention. The front side may be defined as the side facing the substrate 112. The back side may be defined as the side facing the magnetron 166. At step 810, a layer of film is deposited on the substrate 112. The layer of film may be made of material that has been dislodged from the sputtering target 164 during a PVD process. At step 820, the thickness of the film is measured. The thickness of the film may be determined from a two dimensional contour image of the film. However, other means commonly known by persons with ordinary skill in the art may be used to measure the thickness of the film. In addition to or in lieu of measuring the thickness of the film, the sheet resistance of the film may be measured. Sheet resistance is inversely proportional to thickness. At step 830, one or more areas on the film having an undesired thickness are identified. In one embodiment, one or more areas on the film having a thickness less than a desired thickness are identified. For example, a desired thickness for Al or Mo film is between about 2000 Å and 3000 Å. In another embodiment, one or more areas on the film having a thickness greater than a desired thickness are identified. At step 840, the electromagnetic field across the front side of the target is adjusted. In one embodiment, the electromagnetic field that corresponds with the identified areas may be adjusted. As such, the electromagnetic field may be adjusted by adjusting one or more magnet pieces that correspond with the identified areas. In another embodiment, the electromagnetic field that corresponds with one or more areas adjacent the identified areas may be adjusted. As such, the electromagnetic field may be adjusted by adjusting one or more magnet pieces adjacent the magnet pieces that correspond with the identified areas.

In an embodiment in which the areas on the film have a thickness less than a desired thickness, the electromagnetic field across the front side of the sputtering target that corresponds with the identified areas may be increased. In one embodiment, the magnet pieces that correspond with the identified areas may be replaced with stronger magnet pieces. In addition to or in lieu of replacing the magnet pieces with stronger ones, the distance between the magnet pieces that correspond with the identified areas may be decreased. For example, the distance between one or more magnet pieces having opposite polarity may be decreased to increase the electromagnetic field across the front side of the sputtering target that corresponds with the identified areas. Such distance may be illustrated in FIG. 7 as the mesa 708, which represents the gap between the opposed poles.

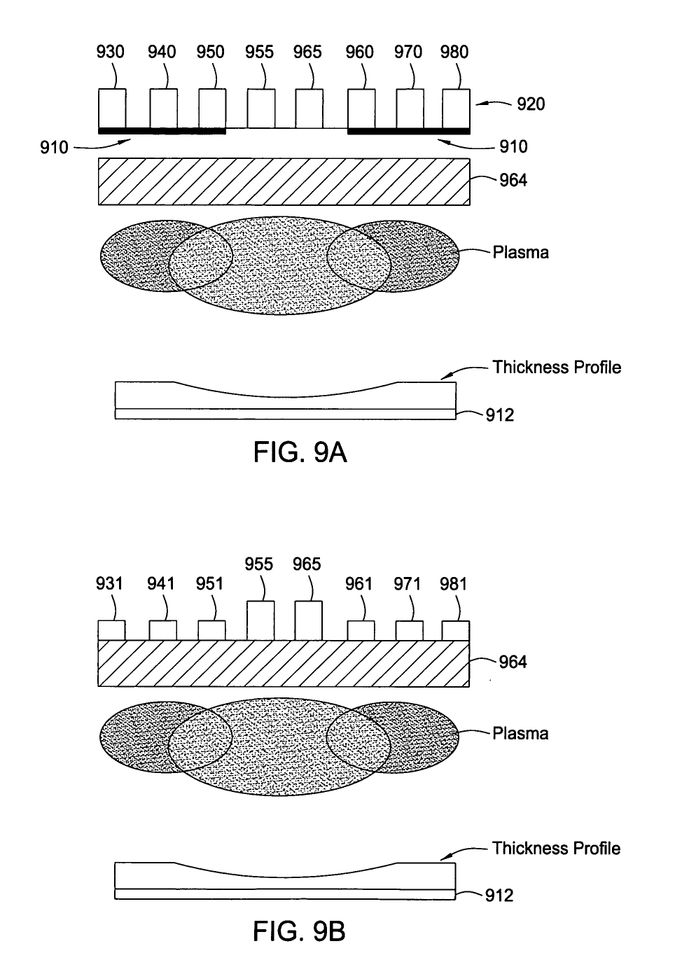

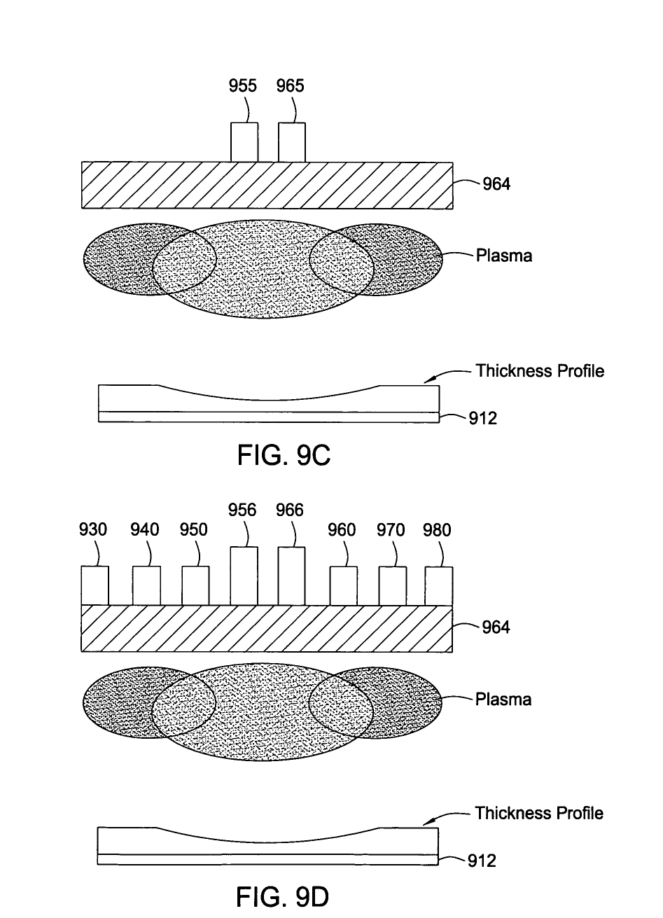

Alternatively, the electromagnetic field that corresponds with areas adjacent the areas having a thickness less than the desired thickness may be reduced. In one embodiment, a metal sheet may be placed between the sputtering target and one or more magnet pieces adjacent the magnet pieces that correspond with the identified areas. FIG. 9A illustrates a schematic diagram of a metal sheet 910 being disposed between a sputtering target 964 and a magnetron 920 in accordance with one or more embodiments of the invention. In one embodiment, the metal sheet 910 is attached to the magnetron 920, leaving a gap between the metal sheet 910 and the sputtering target 964. In particular, the metal sheet 910 is disposed between the sputtering target 964 and magnet pieces 930, 940, 950, 960, 970 and 980, which are adjacent to magnet pieces 955 and 965, which correspond with areas having a thickness less than the desired thickness. In this manner, the electromagnetic field across the front side of the sputtering target 964 that correspond with magnet pieces 930, 940, 950, 960, 970 and 980 is reduced such that the areas that correspond with magnet pieces 930, 940, 950, 960, 970 and 980 and the areas that correspond with magnet pieces 955 and 965 have substantially the same thickness. The metal sheet may be made of any metallic or magnetic material, such as nickel or cobalt.

The electromagnetic field that corresponds with areas adjacent the areas having a thickness less than the desired thickness may also be reduced by increasing the distance between one or more magnet pieces adjacent the magnet pieces that correspond with the identified areas. The electromagnetic field may also be reduced by replacing one or more magnet pieces adjacent the magnet pieces that correspond with the identified areas with weaker magnet pieces. In this manner, the thickness of the areas adjacent the identified areas is reduced so that the layer of film has a substantially uniform thickness.

In an embodiment in which the areas on the film have a thickness greater than a desired thickness, the electromagnetic field across the front side of the sputtering target that corresponds with the identified areas may be reduced. In one embodiment, the electromagnetic field may be reduced by replacing the magnet pieces that correspond with the identified areas with weaker pieces. As an example, FIG. 9B illustrates that magnet pieces 930, 940, 950, 960, 970 and 980 have been replaced with weaker magnet pieces 931, 941, 951, 961, 971 and 981 respectively. In another embodiment, those magnet pieces may be completely removed. As an example, FIG. 9C illustrates that magnet pieces 930, 940, 950, 960, 970 and 980 have been removed. In yet another embodiment, a metal sheet may be placed between the sputtering target and the magnet pieces that correspond with the identified areas. In still yet another embodiment, the electromagnetic field may be reduced by increasing the distance between the magnet pieces.

Alternatively, the electromagnetic field that corresponds with areas adjacent the areas having a thickness greater than the desired thickness may be increased. In one embodiment, the electromagnetic field may be increased by replacing one or more magnet pieces adjacent the pieces that correspond with the identified areas with stronger magnet pieces. As an example, FIG. 9D illustrates magnet pieces 955 and 965 have been replaced with stronger magnet pieces 956 and 966 respectively. In another embodiment, the distance between the magnet pieces adjacent the pieces that correspond with the identified areas may be decreased.

Various adjustment embodiments of the invention described above may be used in combination. For example, the electromagnetic field across the front side of the sputtering target that corresponds with areas on the film having a thickness less than a desired thickness may be increased by replacing the magnet pieces that correspond with the identified areas with stronger magnet pieces and decreasing the distance between the stronger magnet pieces. Likewise, the electromagnetic field across the front side of the sputtering target that corresponds with areas of the film having a thickness greater than a desired thickness may be reduced by replacing the magnet pieces that correspond with the identified areas with weaker pieces, placing a metal sheet between the sputtering target and the magnet pieces, and increasing the distance between the magnet pieces.

While the foregoing is directed to embodiments of the present invention, other and further embodiments of the invention may be devised without departing from the basic scope thereof, and the scope thereof is determined by the claims that follow.

What is claimed is:

1. A method for adjusting an electromagnetic field across a front side of a sputtering target disposed inside a chamber, comprising:
depositing a layer of film on a substrate disposed facing the front side of the sputtering target, wherein the layer of film comprises material from the target;
identifying one or more areas on the layer of film having an undesired thickness; and
adjusting one or more magnet pieces that correspond with the areas on the layer of film having the undesired thickness, wherein the magnet pieces are disposed on a back side of the sputtering target and the back side is opposite of the front side.

2. The method of claim 1, wherein adjusting the magnet pieces comprises increasing the strength of the magnet pieces that correspond with the areas on the layer of film having the undesired thickness, if the undesired thickness is less than a desired thickness.

3. The method of claim 1, wherein adjusting the magnet pieces comprises replacing the magnet pieces that correspond with the areas on the layer of film having the undesired thickness with one or more magnet pieces with greater strength, if the undesired thickness is less than a desired thickness.

4. The method of claim 1, wherein adjusting the magnet pieces comprises decreasing the distance between the magnet pieces that correspond with the areas on the layer of film having the undesired thickness, if the undesired thickness is less than a desired thickness.

5. The method of claim 1, further comprising disposing a metal sheet between the sputtering target and one or more magnet pieces adjacent the magnet pieces that correspond with the areas on the layer of film having the undesired thickness, if the undesired thickness is less than a desired thickness.

6. The method of claim 1, wherein adjusting the magnet pieces comprises disposing a metal sheet between the sputtering target and the magnet pieces that correspond with the areas on the layer of film having the undesired thickness, if the undesired thickness is greater than a desired thickness.

7. The method of claim 1, wherein adjusting the magnet pieces comprises removing the magnet pieces that correspond with the areas on the layer of film having the undesired thickness, if the undesired thickness is greater than a desired thickness.

8. The method of claim 1, wherein adjusting the magnet pieces comprises replacing the magnet pieces that correspond with the areas on the layer of film having the undesired thickness with weaker magnet pieces, if the undesired thickness is greater than a desired thickness.

9. The method of claim 1, wherein adjusting the magnet pieces comprises increasing the distance between the magnet pieces that correspond with the areas on the layer of film having the undesired thickness, if the undesired thickness is greater than a desired thickness.

10. A physical vapor deposition chamber, comprising:
a sputtering target;
a magnetron disposed on a back side of the sputtering target;
a metal sheet disposed between at least a portion of the magnetron and the sputtering target to reduce the effect of the magnetic strength of the portion of the magnetron on the sputtering target; and
a substrate support for holding a substrate.

11. The physical vapor deposition chamber of claim 10, wherein the magnetron comprises one or more removable magnet pieces in operation.

12. The physical vapor deposition chamber of claim 10, wherein the strength of the magnetron is adjustable.

13. The physical vapor deposition chamber of claim 12, wherein the strength of the magnetron is adjustable by replacing at least one of the removable magnet pieces with a stronger magnet piece.

14. The physical vapor deposition chamber of claim 12, wherein the strength of the magnetron is adjustable by replacing at least one of the removable magnet pieces with a weaker magnet piece.

15. The physical vapor deposition chamber of claim 12, wherein the strength of the magnetron is adjustable by removing at least one of the removable magnet pieces.

16. The physical vapor deposition chamber of claim 12, wherein the strength of the magnetron is adjustable by increasing the distance between the removable magnet pieces.

17. The physical vapor deposition chamber of claim 10, wherein the metal sheet is made of nickel or cobalt.

18. A method for processing a substrate in a physical vapor deposition chamber, comprising:
providing a sputtering target;
providing a magnetron on a back side of the sputtering target; and
changing the configuration of the magnetron to increase uniformity of deposition on the substrate.

19. The method of claim 18, wherein the magnetron comprises one or more removable magnet pieces.

20. The method of claim 19, wherein changing the configuration of the magnetron comprises replacing at least one of the removable magnet pieces with a stronger magnet piece.

21. The method of claim 19, wherein changing the configuration of the magnetron comprises replacing at least one of the removable magnet pieces with a weaker magnet piece.

22. The method of claim 19, wherein changing the configuration of the magnetron comprises removing at least one of the removable magnet pieces.

23. The method of claim 19, wherein changing the configuration of the magnetron comprises increasing the distance between the removable magnet pieces.

24. The method of claim 19, wherein changing the configuration of the magnetron comprises decreasing the distance between the removable magnet pieces.

25. The method of claim 18, further comprising adding a metal sheet between the magnetron and the sputtering target to further increase the uniformity of deposition on the substrate.
